(19) United States
(12) Patent Application Publication
(10) Pub. No.: US 2013/0001752 A1
(43) Pub. Date: Jan. 3, 2013

(54) METHOD OF SEMICONDUCTOR MANUFACTURING PROCESS

(75) Inventors: YewChung Sermon Wu, HSINCHU CITY (TW); Yu-Chung Chen, HSINCHU CITY (TW)

(73) Assignee: NATIONAL CHIAO TUNG UNIVERSITY, HSINCHU CITY (TW)

(21) Appl. No.: 13/415,251

(22) Filed: Mar. 8, 2012

(30) Foreign Application Priority Data
Jun. 29, 2011 (TW) 100122950

(51) Int. Cl. H01L 29/06; H01L 21/302; H01L 21/26

(52) U.S. Cl. 257/622; 438/455; 438/795; 438/689; 257/E29.005; 257/E21.328; 257/E21.214

(57) ABSTRACT

The present invention related to a method for manufacturing a semiconductor, comprising steps of: providing a growing substrate; forming on the growing substrate to have plural grooves; forming a semiconductor element layer on the growing substrate; and changing the temperature of the growing substrate and the semiconductor element layer so as to separate the semiconductor element layer from the growing substrate.

### FIELD OF INVENTION

The present invention relates to a semiconductor manufacturing process, and more particularly to a lift-off method in a semiconductor manufacturing process.

### BACKGROUND

In the conventional process of the light-emitting diode (LED), a sapphire (AL₂O₃) substrate, whose crystal structure is similar to that of Gallium Nitride (GaN), is generally chosen to be a growing substrate. However, the sapphire substrate has the worse electrical conductivity and thermal conductivity, and thus, the GaN LED has the defect that thermal dissipation is poor, the reliability of LED is bad, and the emitting area and efficiency of the LED chip are affected under high-current, high-power and long-time operations. Therefore, the manufacture of LEDs and the raising for the emitting efficiency are hindered.

In order to improve the above-mentioned defects, a conventional method is to remove the sapphire substrate. In the prior art, the nitride semiconductor elements are shifted from the sapphire growing substrate to a bonding substrate by a wafer bonding technique so as to raise the characteristics of the LEDs. Namely, the GaN epitaxial layer is lifted off from the sapphire substrate, and is shifted to a substrate with high electric conductivity and high thermal conductivity. In the above-mentioned process, the laser lift-off technique is usually applied to remove the sapphire growing substrate. However, the laser lift off technique degrades the characteristics of the LED elements and affects the yield thereof. Besides, the laser lift-off technique is high cost. Therefore, if the nitride semiconductor elements can be lifted off from the growing substrate during the wafer bonding process without applying the laser lift-off technique, the manufacturing costs would be highly reduced.

Therefore the applicant attempts to deal with the above situation encountered in the prior art.

### SUMMARY

In view of the prior art, in the present invention, a novel process technology is provided, in which technology the contact area between the growing substrate and the nitride semiconductor substrate is reduced. In the process of the temperature change due to the heating during the wafer bonding step, since the growing substrate has the expansion coefficient different from that of the nitride semiconductor substrate, the stress become concentrated such that the growing substrate and the nitride semiconductor substrate can lift off from each other. Accordingly, the laser lift-off technique is not demanded in the processing for removing the growing substrate, and thus the cost is effectively reduced.

In accordance with the first aspect of the present invention, a method for manufacturing a semiconductor is provided. The method includes steps of: providing a growing substrate; forming on the growing substrate to have plural grooves; forming a semiconductor element layer on the growing substrate; and changing the temperature of the growing substrate and the semiconductor element layer so as to separate the semiconductor element layer from the growing substrate.

Preferably, the changing step further comprises steps of heating the growing substrate and the semiconductor element layer, and applying a pressure to bond the semiconductor element layer to a bonding substrate.

Preferably, the bonding substrate has a material being one selected from a group consisting of a copper (Cu) material, an aluminum (Al) material, a silicon (Si) material, a diamond material, a copper alloy material, an aluminum alloy material and a combination thereof.

Preferably, the semiconductor element layer is a nitride semiconductor element layer, and the growing substrate has a material being one selected from a group consisting of an alumina (Al2O3) material, a sapphire material, a silicon carbide (SiC) material and a silicon (Si) material.

Preferably, the plural grooves are made through patterning the growing substrate by one of a chemistry wet etching and a dry etching.

Preferably, the chemistry wet etching is performed by a potassium hydroxide (KOH) solution.

Preferably, the method, before the semiconductor element layer forming step, further includes steps of: forming a dielectric layer on an upper surface of the growing substrate; and revealing a region of the upper surface by an exposing, developing and etching method.

Preferably, the method, before the forming on the growing substrate step, further includes a step of: etching the region by a wet etching to form the plural grooves.

Preferably, the wet etching is performed by a hydrogen-fluoride (HF) solution.

Preferably, the dielectric layer has a Silicon dioxide (SiO2) material.

In accordance with the second aspect of the present invention, a method for manufacturing a semiconductor is provided. The method includes steps of: providing a growing substrate having an upper surface; providing a semiconductor element layer having a lower surface on the growing substrate; reducing a contact area between the upper surface and the lower surface; and heating the growing substrate and the semiconductor element layer.

In accordance with the third aspect of the present invention, a method for manufacturing a semiconductor is provided. The method includes steps of: providing a growing substrate having a first surface; providing a semiconductor element layer having a second surface, wherein the second surface is in contact with the first surface; and heating the growing substrate and the semiconductor element layer such that the first surface is separated from the second surface.

In accordance with the fourth aspect of the present invention, a method for manufacturing a semiconductor is provided. The method includes steps of: providing a growing substrate having a first surface; providing a semiconductor element layer having a second surface, wherein the second surface is in contact with the first surface; and causing one of the growing substrate and the semiconductor element layer to be heated such that the first surface and the second surface are separated from each other.

In accordance with the fifth aspect of the present invention, a method for manufacturing a semiconductor is provided. The method includes steps of: providing a growing substrate having a first surface; providing a semiconductor element layer having a second surface, wherein the second surface is in contact with the first surface; and transforming the first surface into an unsmooth surface in order to reduce a contact area between the first surface and the second surface.

In accordance with the sixth aspect of the present invention, a growing substrate for growing a semiconductor element layer thereon to manufacture a semiconductor is provided. The growing substrate includes: a growing substrate body; and an unsmooth surface formed on the growing substrate body in order to reduce a contact area between the semiconductor element layer and the growing substrate.

### BRIEF DESCRIPTION OF THE DRAWINGS

The foregoing and other features and advantages of the present invention will be more clearly understood through the following descriptions with reference to the drawings, wherein:

FIG. 1 is a flowchart in accordance with an embodiment of the present application;

FIGS. 2-4 are structural drawings for illustrating an embodiment of the present application;

FIG. 5 is the flowchart illustrating an embodiment for forming on the growing substrate to have plural grooves;

FIG. 6 illustrates the corresponding structural drawing for illustrating FIG. 5;

FIG. 7(a) and FIG. 7(b) illustrate the corresponding structural drawings for illustrating FIG. 5;

FIG. 8(a) and FIG. 8(b) illustrate the corresponding structural drawings for illustrating FIG. 5; and

FIGS. 9-10 illustrate the corresponding structural drawing for illustrating FIG. 5.

### DETAILED DESCRIPTION OF THE PREFERRED EMBODIMENTS

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

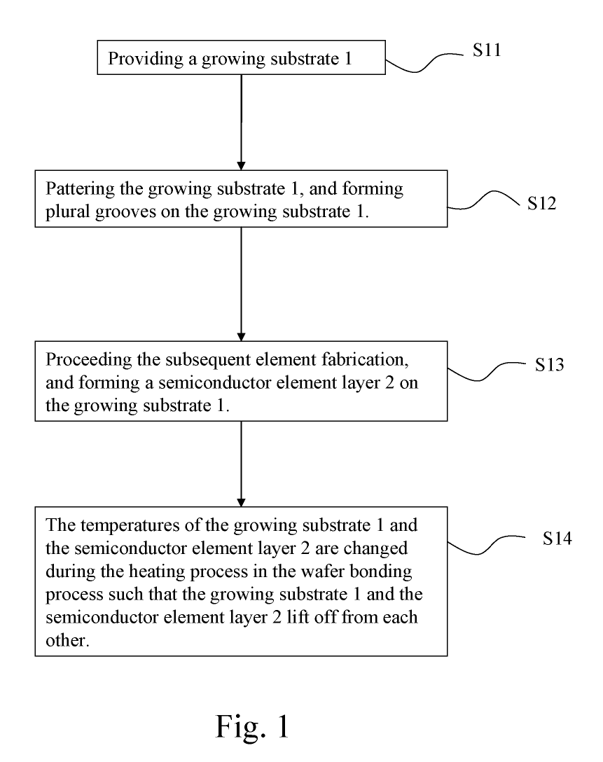

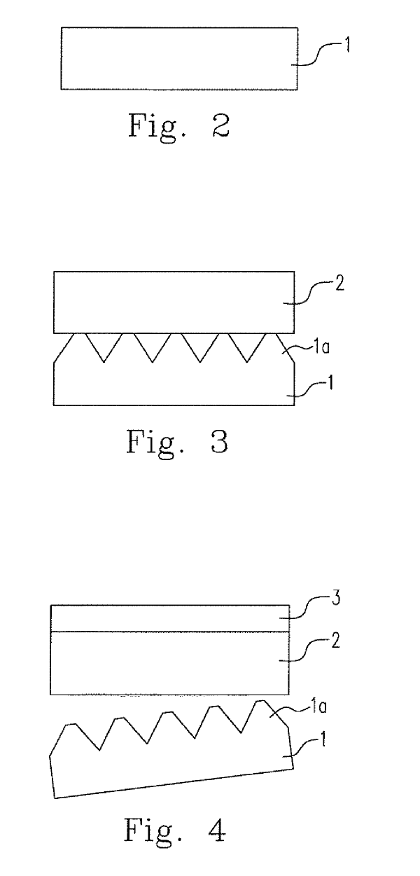

Please refer to FIGS. 1-4, wherein FIG. 1 is a flowchart in accordance with an embodiment of the present application, and FIGS. 2-4 are the structural drawings for illustrating the embodiment of the present application. The embodiment of the present application includes steps S11-S14, which are explained as follows.

Step S11: As shown in FIG. 2, a first substrate, such as a growing substrate 1, is provided. The growing substrate 1 preferably has a material being one selected from a group consisting of an alumina (Al₂O₃) material, a sapphire material, a silicon carbide (SiC) material and a silicon (Si) material.

Step S12: The growing substrate 1 is patterned, such that plural grooves la are formed on the growing substrate 1, as shown in FIG. 3. It would be understood by one skilled that the plural grooves 1a can be formed by patterning the growing substrate 1 through a chemistry wet etching (such as being performed by a potassium hydroxide (KOH)) or a dry etching.

Step S13: The subsequent element fabrication is proceeded, and a semiconductor element layer 2 is formed on the growing substrate 1. The plural grooves 1a formed in Step S12 reduce the contact area between the semiconductor element layer 2 and the growing substrate 1.

Step S14: As shown in FIG. 4, the wafer bonding is proceeded, and the temperature of the growing substrate 1 and the semiconductor element layer 2 is changed during the process of the wafer bonding. The growing substrate 1 and the semiconductor element layer 2 are heated, and receive a pressure such that the semiconductor element layer 2 bonds to a bonding substrate 3, wherein the bonding substrate 3 preferably has a material being one selected from a group consisting of a copper (Cu) material, an aluminum (Al) material, a silicon (Si) material, a diamond material, a copper alloy material and an aluminum alloy material.

The temperatures of the growing substrate 1 and the semiconductor element layer 2 are changed during the wafer bonding process. Since the expansion coefficient of the growing substrate 1 is different from that of the semiconductor element layer 2, the stress is concentrated to the junction between the growing substrate 1 and the semiconductor element layer 2. Further, because the contact area between the growing substrate 1 and the semiconductor element layer 2 is reduced, the growing substrate 1 and the semiconductor element layer 2 lift off from each other.

It would be understood by one skilled in the art that the plural grooves 1a is used for reducing the contact area between the growing substrate 1 and the semiconductor element layer 2, and thus the plural grooves 1a can be formed in any step before the wafer bonding step and after the semiconductor element layer 2 forming step. In addition, the plural grooves 1a is not limited to the regular arrangement in FIGS. 3-4, but all the grooves, such as with linear or dot grooves, causing the contact area between the growing substrate 1 and the semiconductor element layer 2 reduced can reach the affect of the present application.

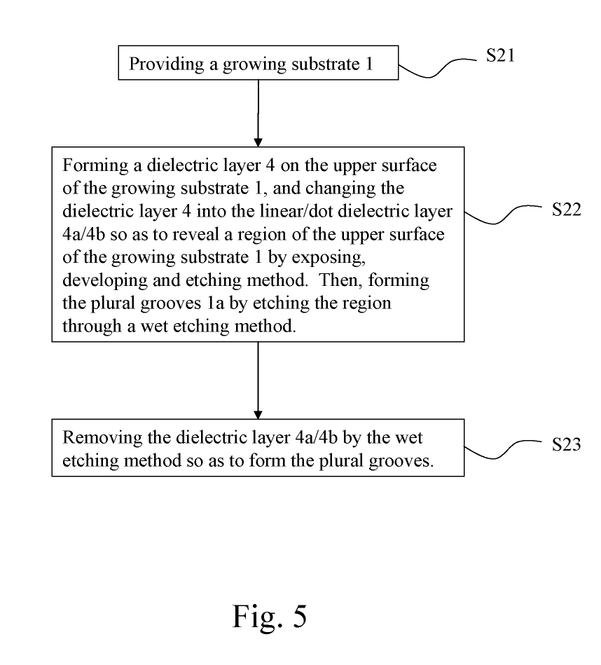

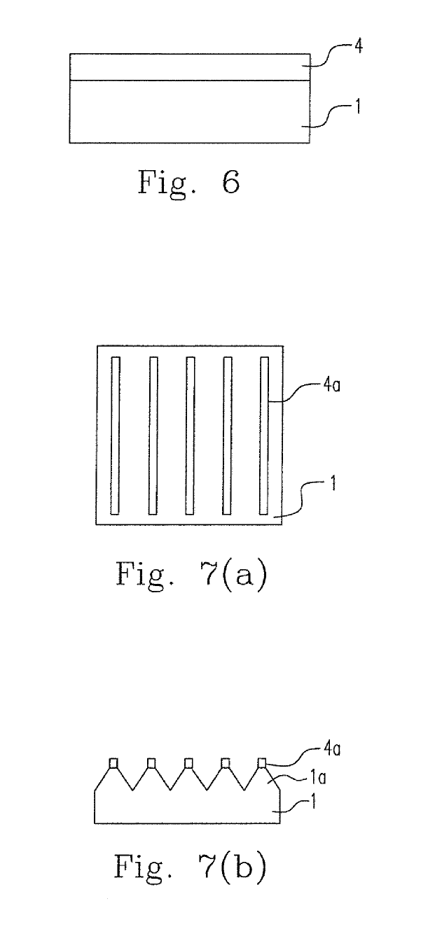

However, the method for forming the above mentioned plural grooves 1a are not limited to the flowchart provided in the abovementioned embodiment. Please refer to FIGS. 5-10, wherein FIG. 5 is the flowchart in accordance with another embodiment of the present application for forming the abovementioned plural grooves, and FIGS. 6-10 illustrate the corresponding structural drawings for illustrating FIG. 5 whose steps are as follows.

Step S21: A growing substrate 1 is provided. As illustrated in the previous embodiment, the growing substrate 1 preferably has a material being one selected from a group consisting of an alumina (Al₂O₃) material, a sapphire material, a silicon carbide (SiC) material and a silicon (Si) material.

Step S22: As shown in Fug. 6, a dielectric layer 4 is formed on the upper surface of the growing substrate 1, and the dielectric layer 4 becomes the linear dielectric layer 4a revealing a region of the upper surface of the growing substrate 1 by exposing, developing and etching method. Then, the plural grooves 1a, as shown in FIG. 7(b), is formed by etching the region through a wet etching method, and FIG. 7(a) is the corresponding top view.

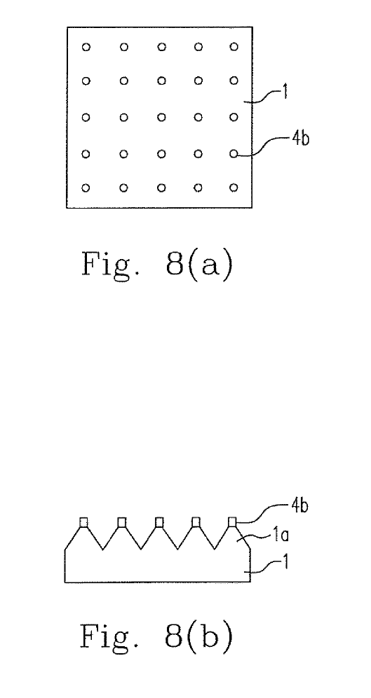

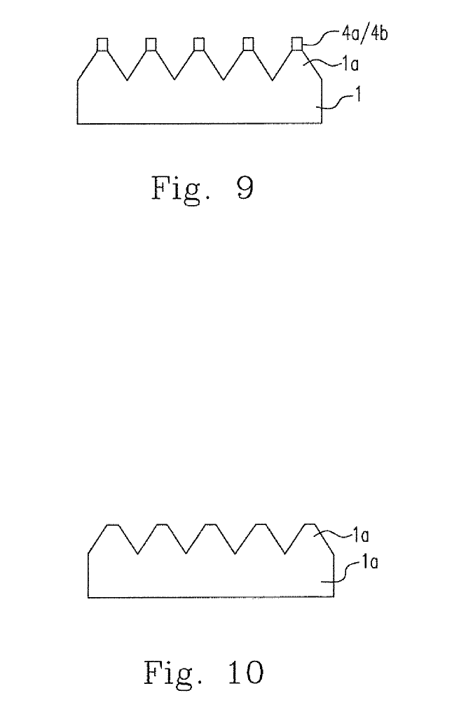

In addition, the dielectric layer 4 can also become the dot dielectric layer 4b revealing a region of the upper surface of the growing substrate 1 by exposing, developing and etching method. Then, the plural grooves 1a, as shown in FIG. 8(b), is formed by etching the region through an etching method, and FIG. 8(a) is the corresponding top view. The top view of the completed plural grooves 1a is shown as FIG. 9, wherein the dielectric layer 4a/4b preferably has a Silicon dioxide (SiO₂) material and the wet etching method is preferably performed by a hydrogen-fluoride (HF) solution.

Step S23: The dielectric layer 4a/4b is removed by the wet etching method so as to form the plural grooves 1a as shown in FIG. 10.

The plural grooves formed in the present invention are not limited to the regularly arranged groove structure illustrated by the abovementioned embodiments. All the groove structures formed between the growing substrate 1 and the semiconductor element layer 2 and the unsmooth surface formed on the growing substrate 1, which renders the contact area between the growing substrate 1 and the semiconductor element layer 2 decreased, can reach the affect of the present application.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A method for manufacturing a semiconductor, comprising steps of:
providing a growing substrate;
forming on the growing substrate to have plural grooves;
forming a semiconductor element layer on the growing substrate; and
changing the temperature of the growing substrate and the semiconductor element layer so as to separate the semiconductor element layer from the growing substrate.

2. The method as claimed in claim 1, wherein the changing step further comprises steps of heating the growing substrate and the semiconductor element layer, and applying a pressure to bond the semiconductor element layer to a bonding substrate.

3. The method as claimed in claim 2, wherein the bonding substrate has a material being one selected from a group consisting of a copper (Cu) material, an aluminum (Al) material, a silicon (Si) material, a diamond material, a copper alloy material, an aluminum alloy material and a combination thereof.

4. The method as claimed in claim 1, wherein the semiconductor element layer is a nitride semiconductor element layer, and the growing substrate has a material being one selected from a group consisting of an alumina (Al₂O₃) material, a sapphire material, a silicon carbide (SiC) material and a silicon (Si) material.

5. The method as claimed in claim 1, wherein the plural grooves are made through patterning the growing substrate by one of a chemistry wet etching and a dry etching.

6. The method as claimed in claim 5, wherein the chemistry wet etching is performed by a potassium hydroxide (KOH) solution.

7. The method as claimed in claim 1, before the semiconductor element layer forming step, further comprising steps of:
forming a dielectric layer on an upper surface of the growing substrate; and
revealing a region of the upper surface by an exposing, developing and etching method.

8. The method as claimed in claim 7, before the forming on the growing substrate step, further comprising a step of:
etching the region by a wet etching to form the plural grooves.

9. The method as claimed in claim 8, wherein the wet etching is performed by a hydrogen-fluoride (HF) solution.

10. The method as claimed in claim 7, wherein the dielectric layer has a Silicon dioxide (SiO₂) material.

11. A method for manufacturing a semiconductor, comprising steps of:
providing a growing substrate having an upper surface;
providing a semiconductor element layer having a lower surface on the growing substrate;
reducing a contact area between the upper surface and the lower surface; and
heating the growing substrate and the semiconductor element layer.

12. A method for manufacturing a semiconductor, comprising steps of:
providing a growing substrate having a first surface;
providing a semiconductor element layer having a second surface, wherein the second surface is in contact with the first surface; and
heating the growing substrate and the semiconductor element layer such that the first surface is separated from the second surface.

13. A method for manufacturing a semiconductor, comprising steps of:
providing a growing substrate having a first surface;
providing a semiconductor element layer having a second surface, wherein the second surface is in contact with the first surface; and
causing one of the growing substrate and the semiconductor element layer to be heated such that the first surface and the second surface are separated from each other.

14. A method for manufacturing a semiconductor, comprising steps of:
providing a growing substrate having a first surface;
providing a semiconductor element layer having a second surface, wherein the second surface is in contact with the first surface; and
transforming the first surface into an unsmooth surface in order to reduce a contact area between the first surface and the second surface.

15. A growing substrate for growing a semiconductor element layer thereon to manufacture a semiconductor, comprising:
a growing substrate body; and
an unsmooth surface formed on the growing substrate body in order to reduce a contact area between the semiconductor element layer and the growing substrate.
